(19) United States
(12) Patent Application Publication
(10) Pub. No.: US 2006/0127823 A1
(43) Pub. Date: Jun. 15, 2006

(54) Multi reticle exposures

(75) Inventors: David J. Sturtevant, Gresham, OR (US); Phong Do, Gresham, OR (US); Dodd Defibaugh, Gresham, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/011,823

(22) Filed: Dec. 14, 2004

(51) Int. Cl. G03F 7/20

(52) U.S. Cl. 430/394; 430/396

(57) ABSTRACT

A method and file structure for exposing images from a plurality of reticles onto a wafer. Multiple images are effectively merged into the same file, which means the wafer need not be unloaded from a stage while exposing multiple reticles. For example, every odd numbered column can contain images from one reticle, and every even numbered column can contain images from a second reticle, where image shifts are used to align the patterns exactly. A continuous pattern is utilized to mimic normal wafer processing.

### BACKGROUND

The present invention generally relates to photolithography, and more specifically relates to using a reticle to expose patterns on a reticle.

Photolithography is used to make integrated circuits. Photolithography is the process of transferring geometric shapes on a reticle to the surface of a silicon wafer. The steps involved in the photolithographic process are wafer cleaning; barrier layer formation; photoresist application; soft baking; reticle alignment; exposure and development; and hard-baking.

A reticle is an optically transparent fused quartz blank imprinted with a pattern defined with chrome metal. The reticle is loaded in a stepper, and the wafer is loaded on an exposure stage. Then, the reticle is aligned with the wafer (x, y, and angle), so that the pattern on the reticle can be transferred onto the wafer surface. The pattern is projected and shrunk by four or five times onto the wafer surface, and a high intensity ultraviolet light is used to expose the photoresist through the pattern on the reticle. To achieve complete wafer coverage, the wafer is repeatedly ‘stepped’ from position to position under the optical column until full exposure is achieved. Each pattern after the first one must be aligned to the previous pattern. Once the reticle has been accurately aligned with the previous pattern on the wafer's surface, the photoresist is again exposed through the pattern on the reticle with a high intensity ultraviolet light. In other words, the pattern is exposed over and over again on the wafer, changing positions each time.

Reticles exist with unique test structures. In many cases, it would be useful to have a single wafer with structures from multiple reticles. However, the file structure of an exposure tool does not allow for use of reticles with different image sizes within the same file.

It is possible to use separate exposure jobs, run consecutively, exposing one reticle on the wafer and then the next. However, when there is a job change on the exposure tool, the wafer is unloaded from the exposure stage and reloaded with the new job to expose the next image. This prevents exact alignment between the different images and prevents the use of multiple reticles for a single wafer.

### OBJECTS AND SUMMARY

An object of an embodiment of the present invention is to provide a system which allows a single wafer to have structures from multiple reticles.

Briefly, an embodiment of the present invention provides a method and file structure for exposing images from a plurality of reticles onto a wafer. Multiple images are effectively merged into the same file, which means the wafer need not be unloaded from a stage while exposing multiple reticles. For example, every odd numbered column can contain images from one reticle, and every even numbered column can contain images from a second reticle, where image shifts are used to align the patterns exactly. A continuous pattern is utilized to mimic normal wafer processing.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 illustrates a method which in accordance with an embodiment of the present invention;

FIG. 2 is a composite wafer map showing all images, columns and rows;

FIG. 3 is similar to FIG. 2, but shows the shifts or offsets relating to each cell of the wafer; and

FIGS. 4 and 5 illustrate the shifts associated with two different cells of the wafer.

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

The present invention generally provides that images from multiple reticles are exposed on a wafer. Multiple images are effectively merged into the same file, which means the wafer need not be unloaded from a stage while exposing multiple reticles. A continuous pattern is utilized to mimic normal wafer processing.

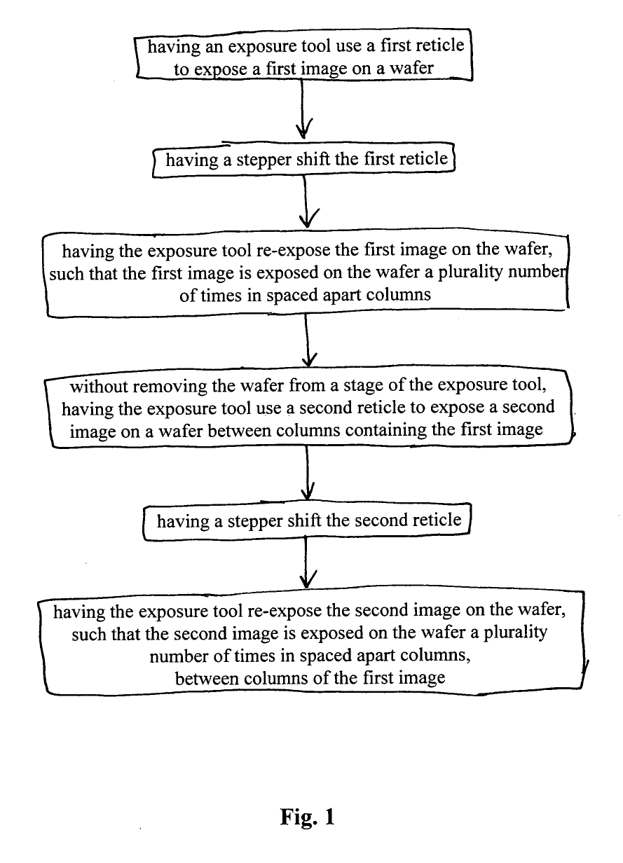

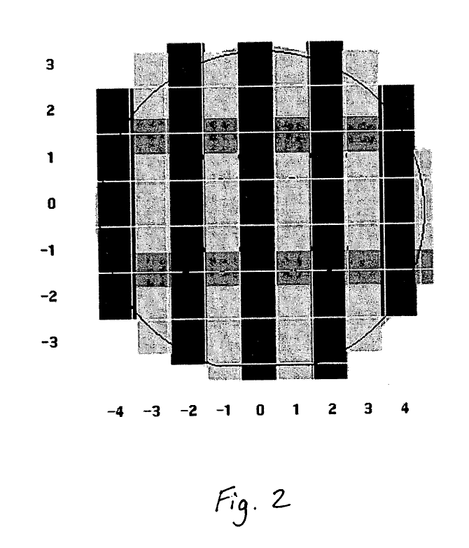

FIG. 1 illustrates a specific embodiment of the present invention, while FIG. 2 illustrates a composite wafer map associated with the method.

As shown in FIG. 1, a file is used to operate an exposure tool/stepper such that the exposure tool exposes a first image from a first reticle onto a wafer which is loaded on the stage of the exposure tool. Then, the stepper shifts the first reticle, and the exposure tool re-exposes the first image on the wafer, such that the first image is exposed on the wafer a plurality number of times in spaced apart columns (in FIG. 2, such columns are identified −4, −2, 0, 2 and 4). Without removing the wafer from the stage of the exposure tool, the exposure tool uses a second reticle to expose a second image on a wafer between columns containing the first image. The stepper is then driven to shift the second reticle, and the exposure tool re-exposes the second image on the wafer, such that the second image is exposed on the wafer a plurality number of times in spaced apart columns (in FIG. 2, such columns are identified −3, −1, 1 and 3), between columns of the first image.

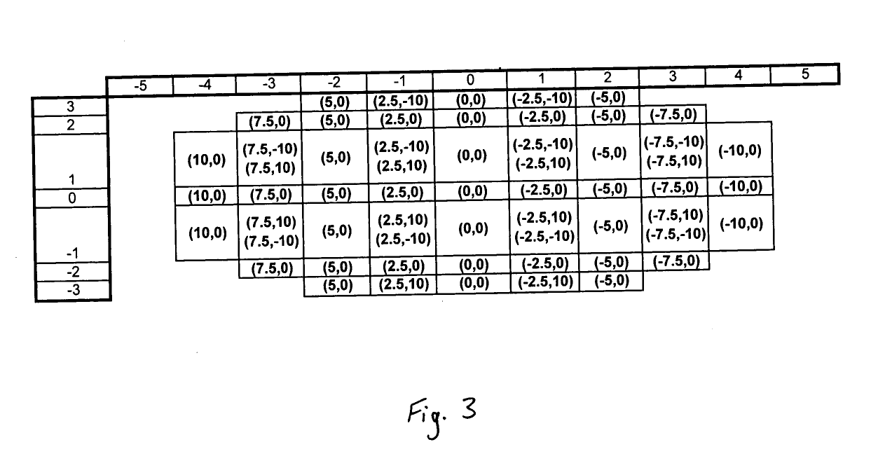

FIG. 3 illustrates shifts which would be used in the case where the first reticle contains an image which is 25 by 30, and the second reticle contains an image which is 20 by 20. For example, the first image is exposed a plurality of times in the center column (the column marked “0” in FIG. 3) with no shift. Each of the images in the following column has a shift in the X direction half the difference (i.e., 25−20=2.5) greater than the previous column's shift.

With regard to the center column (i.e., the column identified 0 in FIGS. 2 and 3), the smaller image is exposed in the adjacent columns (the columns identified “−1” and “1” in FIG. 3) but is shifted in the X direction, toward the center column, by half the difference in the width of the two patterns. As the larger is image is 25 units wide and the smaller image is 20 units wide, the x shift for either column next to the center column is 2.5 units (i.e., half of 5). Hence, the shift in the X direction for each of the images exposed in column “−1” is 2.5, and the shift in the X direction for each of the images exposed in column “1” is −2.5. Each of the images in the following column has a shift in the X direction half the difference (i.e., 25−20=2.5) greater than the previous column's shift. Hence, the X shift of the images exposed in columns −2 and 2 have an X shift of 5 and −5, respectively. Likewise, the X shift of the images exposed in columns −3 and 3 have an X shift of 7.5 and −7.5, respectively. Finally, the X shift of the images exposed in columns −4 and 4 have an X shift of 10 and −10, respectively.

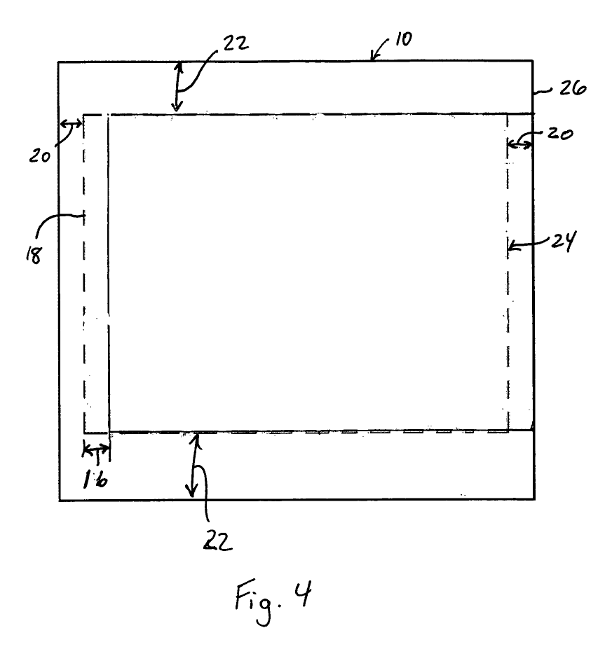

As an example of the shifts discussed herein, FIG. 4 illustrates an example of the shift of the image in column −1, row 0. The cell 10 is 25 by 30, the size of the larger image. The smaller image is to be exposed in this cell and it has been determined that the shift should be 2.5 units in the X direction (dimension 16 in FIG. 3) and that there should be no shift in the Y direction. The dotted line 18 shows where the smaller image would be placed if there were no shift in either direction. As shown, the image would be 2.5 units (dimension 20 in FIG. 3) from the right and left edges of the cell, and 5 units (dimension 22 in FIG. 3) from the top and bottom edges of the cell. The 2.5 unit shift in the X direction provides that the right edge 24 of the image is exposed along the right edge 26 of the cell 10, up against the larger image which has been exposed in column 0, row 0 (see FIG. 2).

While the smaller image which is exposed in the center row (i.e., row 0 as indicated in FIG. 3) has no y shift, the images exposed above and below the center row have shifts in the Y direction. Specifically, for the rows above and below the center, the first shift is equal to the complete Y difference in the heights of the two images (in the example provided, the Y difference in the heights is 10 (30 minus 20)), and the next row out has a shift twice the difference. This is possibly beyond the maximum allowed by the tool software. To circumvent this limitation, a duplicate image of the smaller reticle is created and shifted to abut the previous image. The duplicate is required because an image can be placed with only one shift within a particular cell. This duplicate image is shifted from the same cell as the original, but in the opposite direction. The pattern can then continue as often as needed to complete all the columns relating to the smaller image.

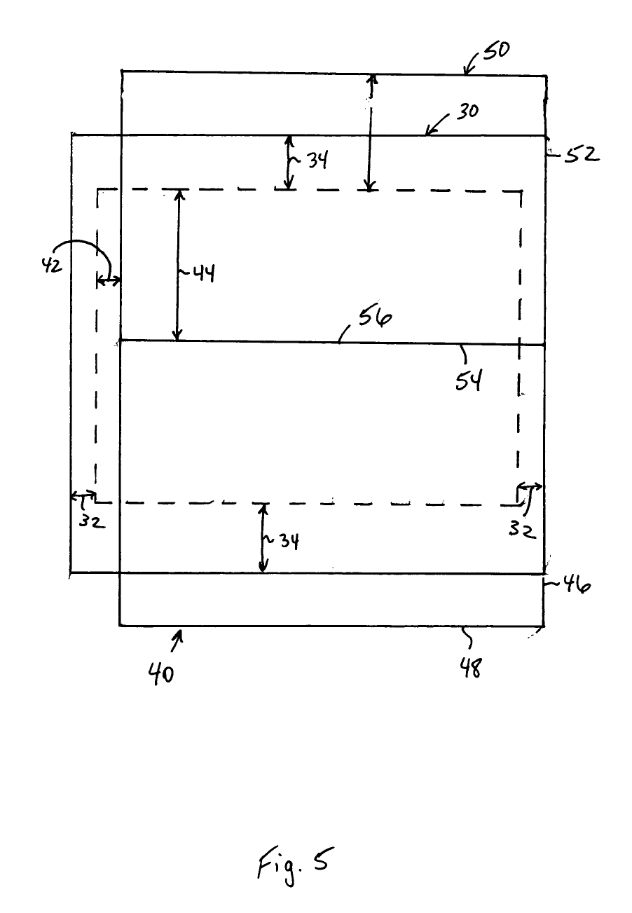

As an example, FIG. 5 illustrates the shifts of the images associated with column −1, row 1. The cell 30 is 25 by 30, the size of the larger image. The smaller image is to be exposed twice relative to this cell and it has been determined that the shift should be 2.5 units in the X direction (half the difference in the widths of the two images) and 10 units in one direction for the first exposure and 10 units in the other direction for the next exposure (where 10 units is the difference in heights of the two images), which provides a duplicate image. The dotted line shows where the smaller image would be placed if there were no shift in either direction. As shown, the image would be 2.5 units (dimension 32) from the right and left edges of the cell, and 5 units (dimension 34) from the top and bottom edges of the cell. With regard to the first image 40, the 2.5 unit shift in the X direction (dimension 42 in FIG. 5) and the −10 unit shift in the Y direction (dimension 44 in FIG. 5) provides that a portion of the right edge 46 of the image 40 is exposed along the right edge of the cell 30, up against the larger image which has been exposed in column 0, row 1 (see FIG. 2), and the remaining right edge 46 of the image is exposed along the right edge of the cell below, up against the larger image which has been exposed in column 0, row 0 (see FIG. 2). Additionally, the bottom edge 48 of the image 40 is exposed along the top edge of the image which has been exposed in column 1, row 0 (see FIG. 2).

The duplicate image 50 is shifted relative the same cell, from the same starting point (i.e., the dotted line in FIG. 5) as image 40. Specifically, image 50 is shifted 2.5 units in the X direction (dimension 42 in FIG. 5) such that a portion of the right edge 52 of the image 50 is exposed along the right edge of the cell 30, up against the larger image which has been exposed in column 0, row 1 (see FIG. 2), and the remaining right edge 52 of the image is exposed along the right edge of the cell above, up against the larger image which has been exposed in column 0, row 1 (see FIG. 2). Additionally, the bottom edge 54 of the image 50 is exposed along the top edge 56 of the image 40 which has been previously exposed relative to the same cell. The shift pattern described in connection with FIGS. 4 and 5 is repeated as often as needed to complete all the columns relating to the smaller image. As such, the shifts identified in FIG. 3 are used.

The present invention generally provides that a file is formed based on an image mapping scheme as discussed above, and the file is thereafter used to drive the exposure tool/stepper such that two reticles are used to expose images on a wafer. Multiple images are merged into the same file which means the wafer is never unloaded from the stage while exposing multiple reticles.

While embodiments of the present invention are shown and described, it is envisioned that those skilled in the art may devise various modifications of the present invention without departing from the spirit and scope of the appended claims.

1. A method of exposing images on a wafer comprising: using a first reticle to expose a first image on the wafer a plurality number of times; and using a second reticle to expose a second image on the wafer a plurality number of times.

2. A method as recited in claim 1, further comprising shifting the first reticle before re-exposing the first image on the wafer, and shifting the second reticle before re-exposing the second image on the wafer.

3. A method as recited in claim 1, further comprising using an exposure tool to expose the images on the wafer, and maintaining the wafer loaded in the exposure tool between using the first reticle and using the second reticle to expose the images on the wafer.

4. A method as recited in claim 3, further comprising using an exposure tool to expose the images on the wafer, and using a file to drive the exposure tool, wherein the file defines shifts that relate to exposures of the first and second images on the wafer.

5. A method as recited in claim 1, further comprising exposing the first image in every other column on the wafer.

6. A method as recited in claim 1, further comprising exposing the second 5 image in every other column on the wafer.

7. A method as recited in claim 1, further comprising exposing the first image in every other column on the wafer, and exposing the second image in adjacent columns.

8. A wafer having a surface and comprising a plurality of number of first images on said surface and arranged in columns, and having a plurality number of second images on said surface arranged in columns.

9. A wafer as recited in claim 8, wherein the first images are arranged in every other column on the surface and the second images are arranged in adjacent columns on the surface.

10. A file for driving an exposure tool to expose images on a wafer, said file comprising means for using a first reticle to expose a first image on the wafer a plurality number of times; and means for using a second reticle to expose a second image on the wafer a plurality number of times.

11. A file as recited in claim 10, further comprising means for shifting the first reticle before re-exposing the first image on the wafer, and means for shifting the second reticle before re-exposing the second image on the wafer.

12. A file as recited in claim 10, further comprising means for exposing the first image in every other column on the wafer.

13. A file as recited in claim 10, further comprising means for exposing the second image in every other column on the wafer.
